(19) United States
(12) Patent Application Publication
(10) Pub. No.: US 2012/0237329 A1
(43) Pub. Date: Sep. 20, 2012

(54) Thin Wafer Gripper Using High Pressure Air

(76) Inventor: Galle Lin, Dallas, TX (US)

(21) Appl. No.: 13/051,059

(22) Filed: Mar. 18, 2011

(51) Int. Cl. H01L 21/677; B25J 15/06

(52) U.S. Cl. 414/754; 294/188

(57) ABSTRACT

The invention concerns thin wafer handling for solar silicone wafers or other semiconductor thin wafer handling applications, especially after back grind process. The invention performs high speed, mass wafer transfer between varying pitch carriers. Transfers are between various types of wafer carriers as required (plastic, Teflon, PEEK, SiC, etc.).

### BACKGROUND OF INVENTION

Conventional mass wafer transfer systems use a comb assembly to lift all the wafers out of a carrier and into a wafer retainer comb assembly. Each wafer comb is made of high purity plastic and has as many “V”-shaped grooves as corresponding to the location and number of wafers in a standard carrier, usually 25, 50, or 100 grooves. The “V” grooves' sloped surfaces are smoothly machined and capable of guiding regular wafers with smooth rounded edges into the valley holding the wafers in an orderly fashion.

This method is suitable for conventional wafers ranging from 75 to 200 mm in diameter with a thickness of 500 to 700 microns. However, after wafers are “back ground” to 100 to 150 microns thickness, they are not as flat as the thicker wafers. The thin wafers are lighter in weight and the originally rounded wafer edges are razor sharp which prevents the wafers from sliding into the “V”. Solar cell wafers have a square edge and back-ground integrated circuit (I. C.) have a sharp edge.

Such edges prevents all wafers from sliding smoothly and fully into the comb. Those wafers will not be transferred correctly and may drop causing wafer breakage. Solar cell wafers are particularly problematic since they can be as thin as 100 microns and weigh less than 3 grams with a square shape.

Conventional wafer transfer designs are based on vacuum gripping with a vacuum pump source and are not able to pick up wafers from a partially filled carrier due to a vacuum pressure drop. This also results in wafer breakage.

Change in pitch is also impossible with conventional methods as the distance between the grooves of the comb assemblies is predefined and the wafers cannot be interlaced.

### BRIEF SUMMARY OF THE INVENTION

The invention is an application of the Bernoulli Principle to generate a low pressure vacuum with a small air jet incorporated in a flat paddle, or wafer gripper, to hold individual wafers. The invention uses an array of 25 to 100 (or more) wafer grippers for mass wafer transfer.

The invention also provides pitch change by transferring wafers between carriers of 4.8 mm and 2.4 mm pitch.

This invention in array is capable of picking up all wafers in a carrier whether full or partially full because there is no vacuum pressure drop. As stated before, conventional designs are not able to pick up wafers from a partially filled carrier due to vacuum pressure drop.

### DETAILED DESCRIPTION OF THE INVENTION

With the application of the Bernoulli Principle, the invention transfers wafers without the use of combs thereby eliminating related problems. The gripper material can be made from but is not limited to aluminum coated with alumina or alumina. The invention is an application of the Bernoulli Principle to generate a low pressure vacuum with a small air jet incorporated in a flat paddle, or wafer gripper, to hold individual wafers (FIG. 1). The air-jet generated low pressure zone can move the wafer from as far as 4 mm to the vacuum gripper surface. The wafers are then transferred directly from a carrier to a receiving carrier. In this manner, the wafer does not experience the problems of being placed into a comb assembly.

An important feature of the invention is no vacuum loss if a carrier is partially filled. If direct vacuum is used to hold wafers, any missing wafers in a carriers would cause a loss in holding force. Also, direct vacuum would create holding force variance in an array and possibly cause wafer damage.

The individual grippers are mounted in arrays that are inserted into carriers. The number of grippers in an array depends on the application and carrier design. The gripper arrays can be oriented vertically or horizontally.

Another advantage of the invention over conventional methods is that it can perform accurate pitch change. For example, grippers in array can combine wafers from two 4.8 mm standard pitch carriers into a 2.4 mm pitch carrier. This process is shown in FIGS. 2, 3, and 4.

### BRIEF DESCRIPTION OF DRAWINGS

The following drawings are referenced:

FIG. 1 is a diagram of the Wafer Gripper using compressed air or liquid N₂ with a side view of grippers in an array.

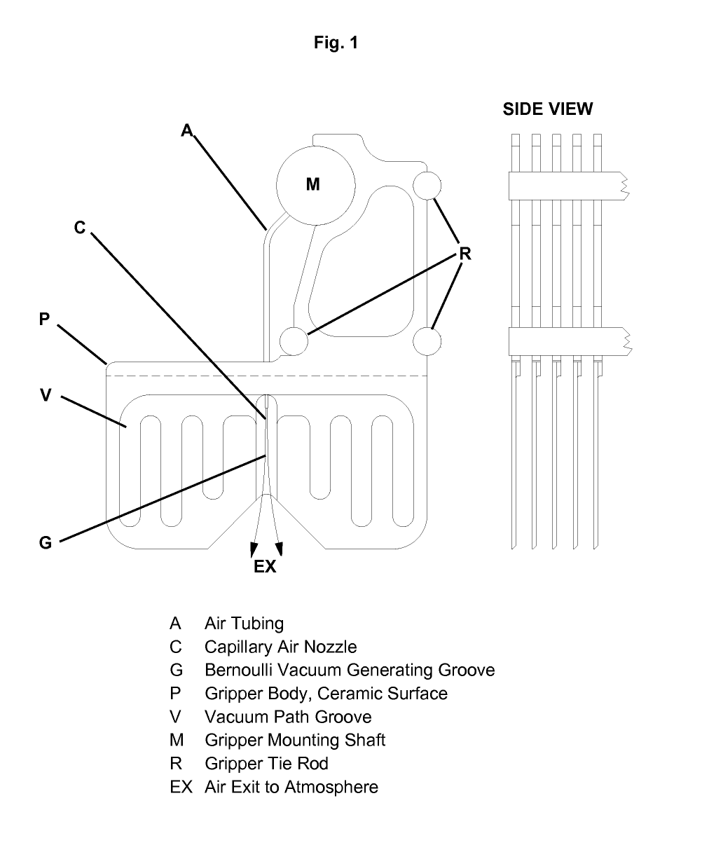

FIG. 2 is a view of Gripper 1 with Wafers from carrier 1 in slot positions 1, 3, 5, 7 . . . (Odd Order).

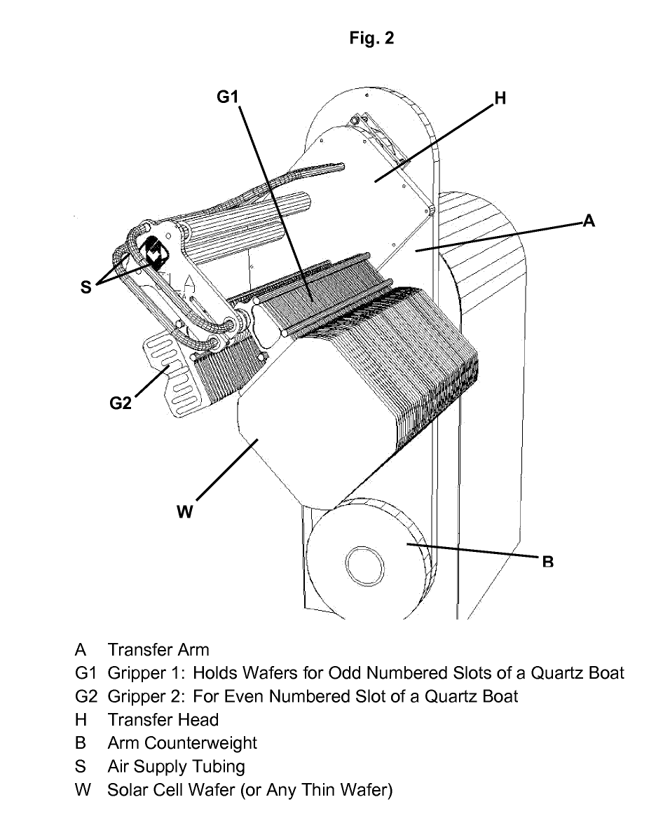

FIG. 3 is a view of Gripper 1 rotated up to clear the pickup position for Gripper 2 to pick up wafers from carrier 2 in slot positions 2, 4, 6, 8 . . . (Even Order). Using 50-slot carriers, at this point, Gripper 1 is holding odd-numbered wafers (1, 3, 5, 7, . . . 49) and Gripper 2 is holding even numbered-wafers (2, 4, 6, 8, . . . 50).

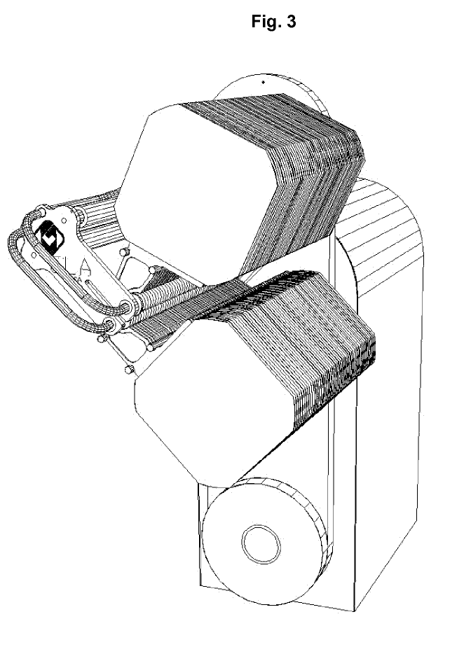

FIG. 4 is a view of Gripper 1 merged with Gripper 2, reducing the pitch of the wafers by half.

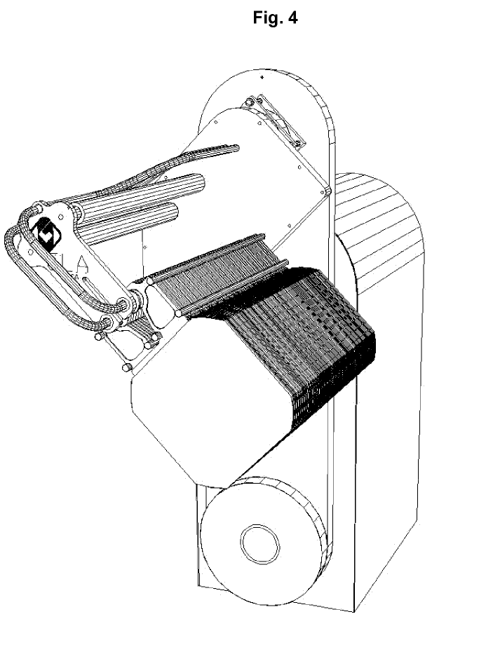

What I claim as my invention is:

1. Thin Wafer Grippers for Mass Wafer Transfer Using High Pressure Air:
Provides mass transfer of wafers of any thickness, regardless of the wafer shape, or edge profile.

2. Mass Transfer with Pitch Change:
Transfers wafers from carrier(s), performs reduced pitch and merge, and loads into receiving carrier(s). The technology provides fast and 100% secure merge during transfer.
